(19) United States
(12) Patent Application Publication
(10) Pub. No.: US 2025/0046693 A1
(43) Pub. Date: Feb. 6, 2025

(54) CHIP PACKAGING STRUCTURE, PACKAGING SUBSTRATE AND MANUFACTURING METHOD THEREOF

(71) Applicant: Smarter Silicon (Shanghai) Technologies Co., Ltd., Shanghai (CN)

(72) Inventors: Xiaorui YANG, Shanghai (CN); WEI-CHIN LIN, Shanghai (CN)

(21) Appl. No.: 18/793,248

(22) Filed: Aug. 2, 2024

(30) Foreign Application Priority Data
Aug. 3, 2023 (CN) 202310975688.4

(51) Int. Cl. H01L 23/498; H01L 21/48; H01L 23/00

(52) U.S. Cl. CPC H01L 23/49822; H01L 21/4857; H01L 23/49838; H01L 24/16; H01L 2224/16227

(57) ABSTRACT

A packaging substrate that includes a first conductive layer to an N^{th} conductive layer stacked in sequence, N being a positive integer greater than 3; an insulating layer arranged between two adjacent conductive layers; a plurality of pads disposed on the first conductive layer, the plurality of pads being used to connect a plurality of conductive bumps at the bottom of a chip; and a plurality of conductive holes arranged one-to-one corresponding to the plurality of pads between the first conductive layer and an a^{th} conductive layer, one end of the conductive hole is connected to the corresponding pad, and the other end extending to the a^{th} conductive layer at most and being electrically connected to a corresponding core conductive hole.

### CROSS-REFERENCES TO RELATED APPLICATION

This application claims priority to Chinese Patent Application No. 202310975688.4 filed on Aug. 3, 2023, the entire content of which is incorporated herein by reference.

### FIELD OF TECHNOLOGY

The present disclosure relates to the field of chip packaging technology and, more specifically, to a chip packaging structure, a packaging substrate and a manufacturing method thereof.

### BACKGROUND

With the continuous development of science and technology, more and more electronic devices are widely used in people's daily life, bringing great convenience to people's daily life, and becoming indispensable and important tools for people today.

The core structure for an electronic device to realize various functions is the chip. In order to protect the chip and facilitate the connection between the chip and external circuits, a chip needs to be packaged and protected. In conventional technology, when packaging and protecting the chip, the spacing between the core conductive holes in the packaging substrate is large, which affects the performance of the chip packaging structure.

### SUMMARY

One aspect of this disclosure provides a packaging substrate for chip packaging. The packaging substrate includes a first conductive layer to an N^{th} conductive layer stacked in sequence, N being a positive integer greater than 3; an insulating layer arranged between two adjacent conductive layers; a plurality of pads disposed on the first conductive layer, the plurality of pads being used to connect a plurality of conductive bumps at the bottom of a chip; and a plurality of conductive holes arranged one-to-one corresponding to the plurality of pads between the first conductive layer and an a^{th} conductive layer, one end of the conductive hole is connected to the corresponding pad, and the other end extending to the a^{th} conductive layer at most and being electrically connected to a corresponding core conductive hole. The a^{th} conductive layer is the first core conductive layer and an a+1th is a second core conductive layer, a being a positive integer, 1<a<N−1. The first core conductive layer and the second core conductive layer are connected via the core conductive hole. The spacing between two adjacent conductive layers is no less than the process standard required for arranging the core conductive hole in the core conductive layer.

Another aspect of the present disclosure provides a method for manufacturing a packaging substrate. The packaging substrate includes a first conductive layer to an N^{th} conductive layer stacked in sequence, and an insulating layer arranged between two adjacent conductive layers. The method includes forming an a^{th} conductive layer and an a+1th conductive layer stacked on each other, the a^{th} conductive layer being a first core conductive layer, the a+1th conductive layer being a second core conductive layer, a being a positive integer, 1<a<N−1, the first core conductive layer and the second core conductive layer being connected via a core conductive hole; sequentially forming an a−1th conductive layer to the first conductive layer on a surface of the a^{th} conductive layer facing away from the a+1th conductive layer; and sequentially forming an a+2th conductive layer to the N^{th} conductive layer on a surface of the a+1th conductive layer facing away from the a^{th} conductive layer. The first conductive layer includes a plurality of pads, the plurality of pads being used to connect conductive bumps at the bottom of a chip. A plurality of conductive holes are arranged one-to-one corresponding to the plurality of pads between the first conductive layer and an a^{th} conductive layer, one end of the conductive hole is connected to the corresponding pad, and the other end extending to the a^{th} conductive layer at most and being electrically connected to a corresponding core conductive hole. The spacing between two adjacent conductive layers is no less than the process standard required for arranging the core conductive hole in the core conductive layer.

Another aspect of the present disclosure provides a chip packaging structure. The chip packaging structure includes a packaging substrate and a chip. The packaging substrate includes a first conductive layer to an N^{th} conductive layer stacked in sequence, an insulating layer arranged between two adjacent conductive layers, and a plurality of pads disposed on the first conductive layer. The chip includes a plurality of conductive bumps at the bottom of the chip. The plurality of conductive bumps are connected and fixed to the plurality of pads in the packaging substrate.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a schematic diagram of a layout of conductive holes in a packaging substrate.

FIG. 2 is a top view of a conductive layer used as a ground plane.

FIG. 3 is a top view of the conductive layer used as a power plane.

FIG. 4 is a top view of the packaging substrate according to an embodiment of the present disclosure.

FIG. 5 is a cross-sectional view of the packaging substrate according to an embodiment of the present disclosure.

FIG. 6 is a schematic diagram of the layout of conductive holes and core conductive holes in the packaging substrate according to an embodiment of the present disclosure.

FIG. 7 is a schematic diagram of the number of extended layers of the conductive holes in the packaging substrate shown in FIG. 6.

FIG. 8 is a simulation test diagram of a loop inductance of a power conductive bump in the packaging substate shown in FIG. 1.

FIG. 9 is a simulation test diagram of the loop inductance of the power conductive bump in the packaging substrate shown in FIG. 4.

FIG. 10 is a graphic structure diagram of the conductive layer according to an embodiment of the present disclosure.

FIG. 11 is another graphic structure diagram of the conductive layer according to an embodiment of the present disclosure.

FIG. 12 is a simulation test diagram of the loop inductance of a grounded conductive bump in the packaging substate shown in FIG. 1.

FIG. 13 is simulation test diagram of the loop inductance of the grounded conductive bump in the packaging substate shown in FIG. 4 combined with fence-type conductive traces.

FIG. 14 is a flowchart of a process for manufacturing a packaging substrate according to an embodiment of the present disclosure.

FIG. 15 is a schematic diagram of a chip packaging structure according to an embodiment of the present disclosure.

### DETAILED DESCRIPTION

The technical solutions of the present disclosure will be described in detail with reference to the drawings. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

As the functions and complexity of system-on-chip (SOC) increase, the number of signals and types of power supplies required also increased. However, due to the design limitation of chip size, the number of conductive bumps corresponding to power supplies and signals is also limited.

From the perspective of chip power supply, the more power conductive bumps there are, the more stable the power delivery network (PDN) in the chip will be. Therefore, in chip design, the number of conductive bumps can be increased by reducing the spacing between the conductive bumps at the bottom of the chip.

However, from the perspective of packaging substrate design, the layout space of signals and power supplies in the packaging substrate is greatly restricted due to considerations such as reducing the cost of the packaging substrate, reducing the size of the packaging substrate, and reducing the number of conductive layers. In particular, the process level of the packaging substrate is often greater than the process level of the chip process. Therefore, the conductive bump spacing in the chip design is not ideal to the packaging substrate design. In order to meet the needs of chip design, the electrical properties of the packaging structure often need to be sacrificed, resulting in poor product performance.

Embodiments consistent with the present disclosure provide a chip packaging structure, a packaging substrate, and a manufacturing method thereof, which improves the circuit layout in the packaging substrate. Simulations have shown that the technical solutions of the present disclosure can ensure the integrity of the chip and package power supply and improve product performance.

To make the above objectives, features, and advantages of the present disclosure more obvious and comprehensible, the present disclosure will be further described in detail below in conjunction with the accompanying drawings and various embodiments.

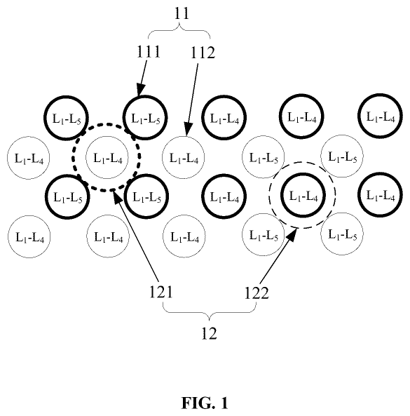

FIG. 1 is a schematic diagram of a layout of conductive holes in a packaging substrate. FIG. 1 is a top view of a front side of the packaging substrate. The packaging substrate has a first metal layer L₁ to an N^{th} metal layer LN stacked in sequence, where N is a positive integer greater than 3. In the embodiments of the present disclosure, N=10 is taken as an example. However, the value of N can be set based on packaging requirements, such as 4, 6, 8, etc., and is not limited to 10.

The a^{th} conductive layer Lₐ is the first core conductive layer, and the a+1th conductive layer Lₐ₊₁ is the second core conductive layer, a being a positive integer, and 1<a<N−1. The first core conductive layer and the second core conductive layer may be connected via core conductive holes 12. In the embodiments of the present disclosure, a=5 is taken as an example for illustration. That is, the fifth conductive layer L₅ and the sixth conductive layer L₆ are the first core conductive layer and the second core conductive layer respectively. The value of a can be set based on the value of N in the packaging circuit board and the circuit layout requirements, and is not limited to the implementation method in which a=5 in the embodiments of the present disclosure. The core conductive holes 12 includes a first core conductive hole 121, represented by a thick dotted circle, and a second core conductive layer 122, represented by a thin dotted circle.

The first metal layer L₁ is the front side of the packaging substrate and has a plurality of pads corresponding to the conductive bumps at the bottom of the chip. The pad may be connected to the corresponding core conductive hole 12 through the conductive hole 11. The conductive hole 11 includes a first conductive hole 111 and a second conductive hole 112. The first conductive hole 111 may be used to connect to the first core conductive hole 121, and the second conductive hole 112 may be used to connect to the second core conductive hole 122. The relatively thick solid circle represents the first conductive hole 111, and the relatively thin solid circle represents the second conductive hole 112. The first conductive hole 111 and the second conductive hole 112 may be used to access different potentials. The first conductive hole 111 may be connected to the conductive bump at the bottom of the chip through its top pad, and the second conductive hole 112 may be connected to the grounding conductive bump at the bottom of the chip through its top pad.

In the packaging substrate, the first conductive layer L₁ to the a−1th conductive layer Lₐ₋₁ above the core conductive layer may have different process standards from the core conductive layer. The first conductive layer L₁ to the a−1th conductive layer Lₐ₋₁ can meet the circuit layout requirements with relatively small hole spacing and conductive trace width. However, the thickness between the two conductive layers is relatively large, thereby having relatively large conductive holes and relatively large conductive hole spacing extending to the first core conductive layer. In this way, as shown in FIG. 1, the spacing between adjacent first core conductive hole 121 and second core conductive hole 122 is relatively large.

Next, a flip chip ball grid array (FC-BGA) packaging substrate is taken as an example to describe the relatively large packaging substrate size caused by the arrangement shown in FIG. 1.

As shown in FIG. 1, part of the first conductive hole 111 extends from the first conductive layer L₁ to the fifth conductive layer L₅. The part of the first conductive hole 111 directly extends to the first core conductive layer, and can be directly connected to the conductive trace of the fifth conductive layer L₅ through the first core conductive hole 121. Another part of the first conductive hole 111 extends from the first conductive layer L₁ to the fourth conductive layer L₄. This part of the first conductive hole 111 needs to be connected to the first conductive hole 111 extending to the fifth conductive layer L₅ based on the conductive trace of the fourth conductive layer L₄ in order to be connected to the first core conductive hole 121. Similarly, in FIG. 1, part of the second conductive hole 112 extends from the first conductive layer L₁ to the fifth conductive layer L₅, and another part of the second conductive hole 112 extends from the first conductive layer L₁ to the fourth conductive layer L₄, and is connected to the second core conductive hole 122 based on the conductive traces of the fifth conductive layer L₅ and the fourth conductive layer L₄. In FIG. 1, L₁-L₅ indicates a conductive hole extending from the first conductive layer L₁ to the fifth conductive layer L₅, and L₁-L₄ indicates a conductive hole extending from the first conductive layer L₁ to the fourth conductive layer L₄.

In the embodiment shown in FIG. 1, the spacing between two adjacent conductive holes 11 (that is, the spacing between the first conductive hole 111 and the second conductive hole 112) is arranged based on the process standard in the non-core conductive layer. In this way, even though the integration can be improved, the adjacent first conductive hole 111 and second conductive hole 112 cannot be extended to the fifth conductive layer L₅ due to the relatively large core conductive holes and conductive traces in the core conductive layer. Otherwise, the spacing between the two cannot meet the layout requirements of the conductive trace segments in the core conductive layer, resulting in short circuit. Therefore, as shown in FIG. 1, in the direction perpendicular to the packaging substrate, the first conductive hole 111 extending to the fifth conductive layer L₅ and the second conductive hole 112 extending to the fifth conductive layer L₅ need to be separated by at least one row of first conductive holes 111 extending to the fourth conductive layer L₄ and one row of second conductive holes 112 extending to the fourth conductive layer L₄. In this way, there is a relatively large spacing between the adjacent first core conductive holes 121 and second core conductive holes 122. The increase in the spacing increases the loop inductance in the chip packaging structure, thereby affecting the performance of the chip packaging structure.

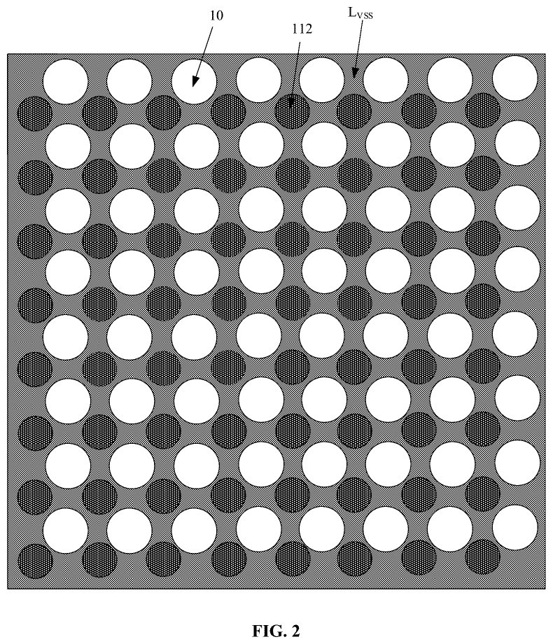

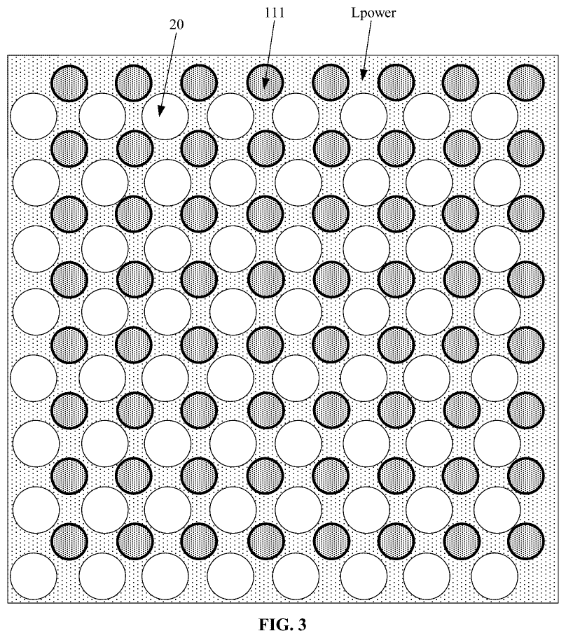

FIG. 2 is a top view of a conductive layer used as a ground plane, and FIG. 3 is a top view of the conductive layer used as a power plane. The embodiment shown in FIG. 1 generally adopts the design of alternating group plane Lᵥₛₛ and power plane L_{power}. For example, the first conductive layer L₁ and the third conductive layer L₃ may both be ground planes, and the second conductive layer L₂ and the fourth conductive layer L₄ may both be power planes.

As shown in FIG. 2, for the group plane Lᵥₛₛ, the entire conductive layer may have the same potential, and each second conductive hole 112 may be connected to the conductive layer. In addition, the conductive layer may have a plurality of first hollow regions 10 corresponding to the first conductive holes 111 one-by-one. The size of the first hollow regions 10 may be larger than the aperture of the first conductive hole 111 such that the first conductive holes 111 can pass through the group plane Lᵥₛₛ without contact.

As shown in FIG. 3, the power plane L_{power}, the entire conductive layer may have the same potential, and each of the first conductive holes 111 may be connected to the conductive layer. In addition, the conductive layer may have a plurality of second hollow regions 20 corresponding to the second conductive holes 112. The size of the second hollow regions 20 may be larger than the aperture of the second conductive holes 112 such that the second conductive holes 112 can pass through the power plane L_{power} without contact.

Corresponding to the design shown in FIG. 2 and FIG. 3, the defect from the packaging perspective is that the conductive layer needs to be provided with a relatively high proportion of hollow regions, resulting in a low utilization rate of the conductive layer. The defect from the electrical perspective is that the grounding conductive bump is too strongly connected, resulting in insufficient connection of the power conductive bump, which leads to a low loop inductance of the power conductive bump.

Based on the embodiment shown in FIG. 1 to FIG. 3, an embodiment of the present disclosure provides a packaging substrate with a smaller core conductive hole spacing, which can reduce the loop inductance of the packaging substrate and improve power integrity.

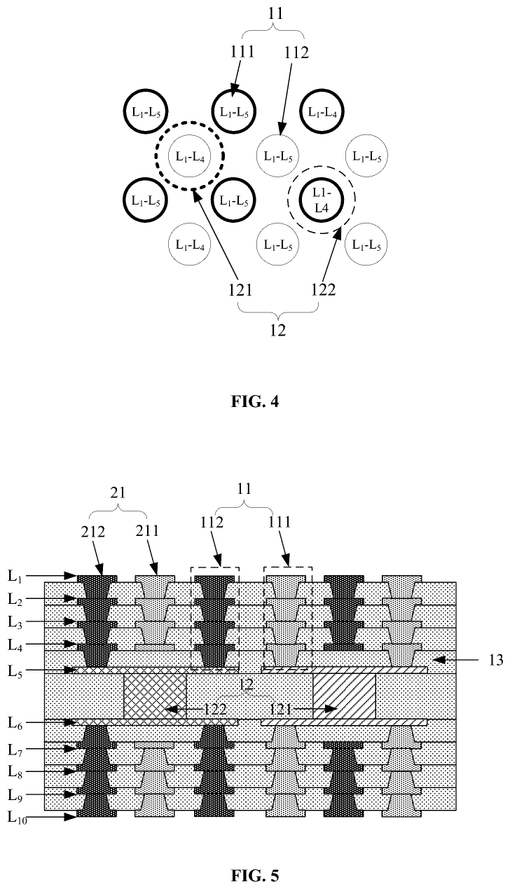

FIG. 4 is a top view of the packaging substrate according to an embodiment of the present disclosure, and FIG. 5 is a cross-sectional view of the packaging substrate according to an embodiment of the present disclosure. The packaging substrate shown may be used for chip packaging.

The packaging substrate may include a first conductive layer L₁ to an N^{th} conductive layer LN stacked in sequence. An insulting layer 13 may be provided between two adjacent conductive layers, N being a positive integer greater than 3.

In some embodiments, the first conductive layer L₁ may include a plurality of pads 21, which can be used to connect the conductive bumps at the bottom of the chip.

The a^{th} conductive layer Lₐ may be the first core conductive layer, the a+1th conductive layer Lₐ₊₁ may be the second core conductive layer, a being a positive integer, and 1<a<N−1. The first core conductive layer and the second core conductive layer may be connected via a core conductive hole 12.

In some embodiments, a plurality of conductive holes 11 corresponding to the pads 21 may be arranged between the first conductive layer L₁ and the a^{th} conductive layer Lₐ. One end of the conductive hole 11 may be connected to the corresponding pad 21, and the other end may extend to the a^{th} conductive layer Lₐ at most and may be electrically connected to the corresponding core conductive hole 12.

In some embodiments, the spacing between two adjacent conductive holes 11 may not be less than the process standard required for laying out the core conductive holes 12 in the core conductive layer.

The spacing between two adjacent conductive holes 11 may be set to be no less than the process standard required for the layout of the core conductive holes 12 in the core conductive layer, thereby increasing the spacing between the two adjacent conductive holes 11 connected to different potentials. In this way, two adjacent conductive holes 11 connected to different potentials can be extended to the first core conductive layer, thereby reducing the spacing between the conductive holes 12 connected to the two conductive holes 11.

In the packaging substrate provided in this embodiment of the present disclosure, the spacing between two adjacent conductive holes 11 may be set to be no less than the process standard required for arranging the core conductive holes 12 in the core conductive layer. Compared with the embodiment shown in FIG. 1 to FIG. 3, the spacing between two adjacent conductive holes 11 is increased. In this way, the spacing between two adjacent core conductive holes 12 can be reduced, thereby reducing the loop inductance and improving the performance of the chip packaging structure.

As shown in FIG. 5, the number of conductive layers from the first conductive layer L₁ to the a^{th} conductive layer Lₐ is the same as the number of the a+1^{th} conductive layer Lₐ₊₁ to the N^{th} conductive layer LN; the conductive holes 11 in the a+1^{th} conductive layer Lₐ₊₁ to the N^{th} conductive layer LN are symmetrically arranged with the conductive holes 11 in the first conductive layer L₁ to the a^{th} conductive layer Lₐ; the conductive traces 30 in the a+1^{th} conductive layer Lₐ₊₁ to the N^{th} conductive layer LN are symmetrically arranged with the conductive traces 30 in the first conductive layer L₁ to the a^{th} conductive layer Lₐ. The symmetrical structural design facilitates the process preparation of the packaging substrate and enables the packaging substrate to have better electrical properties. In the packaging substrate, for the pad 21 used to connect the chip power conductive bump, in order to minimize the length of the wire between the chip and the external power supply, generally no fa-out design is used, such that the packaging substrate can adopt a symmetrically design in both upper and lower parts. It should be noted that in other embodiments, the structure between the a+1^{th} conductive layer Lₐ₊₁ to the N^{th} conductive layer LN may also adopt a symmetric structure different from that between the first conductive layer L₁ to the a^{th} conductive layer Lₐ. For example, the number of conductive holes on the surface of the N^{th} conductive layer LN may be appropriately reduced by using lateral interconnection, and the pad spacing on the back of the packaging substrate may appropriately increase.

As described below, between the first conductive layer L₁ and the a^{th} conductive layer Lₐ, the conductive hole 11 that does not extend to the a^{th} conductive layer Lₐ may be connected to the conductive hole 11 extending to the a^{th} conductive layer Lₐ through other conductive layers above the a^{th} conductive layer Lₐ, thereby realizing the connection with the corresponding core conductive hole 12.

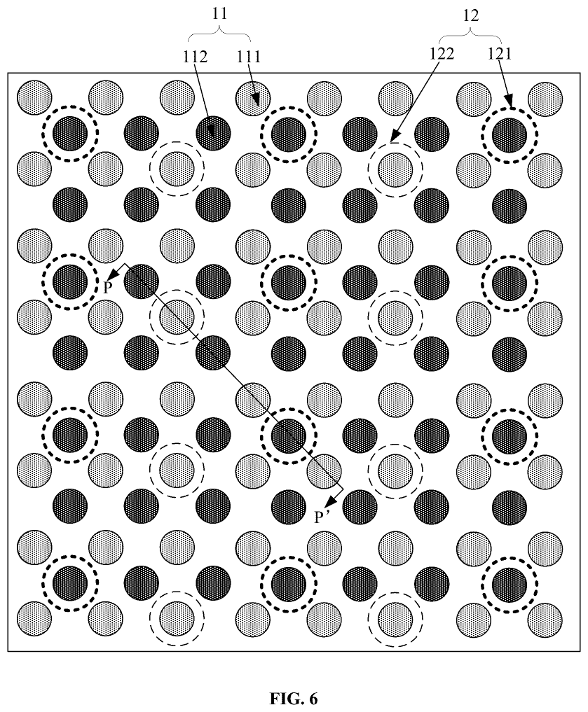

FIG. 6 is a schematic diagram of the layout of conductive holes and core conductive holes in the packaging substrate according to an embodiment of the present disclosure, and FIG. 5 is a cross-sectional view of FIG. 6 in the P-P′ direction.

As shown in FIG. 4 to FIG. 6, the plurality of pads 21 in the first conductive layer L₁ includes a plurality of first pads 211 arranged in an array, the conductive holes 11 connected to the first pads 211 being first conductive holes 111; a plurality of second pads 212 arranged in an array, the conductive holes 11 connected to the second pads 212 being second conductive holes 112; a second pad 212 arranged between each of the four first pads 211 defined by two adjacent rows and two adjacent columns. In some embodiments, the first conductive hole 111 and the conductive hole 12 may be used to access different potentials, and the spacing between the first conductive hole 111 and the second conductive hole 112 may not be less than the process standard required for the layout of the core conductive hole 12 in the core conductive layer.

The conductive bumps at the bottom of the chip may include power conductive bumps and grounding conductive bumps, which can be used to connect to power and ground respectively. The first pad 211 in the conductive layer L₁ may be used to connect the power conductive bump, and the second pad 212 may be used to connect the grounding conductive bump.

The pads 21 may be arranged opposite to the conductive bumps at the bottom of the chip in a one-to-one relationship, and the pads may also be arranged opposite the conductive holes 11 in a one-to-one relationship. Therefore, the pads 21, the conductive bumps and the conductive holes 11 can have the same arrangement.

All first conductive holes 111 may be arranged in an array, and all second conductive holes 112 may be arranged in an array. The array of the first conductive holes 111 and the array of the second conductive holes 112 may be staggered and nested. More specifically, for the array formed by the first conductive holes 111, a second conductive hole 112 may be correspondingly arranged in the middle area of four first conductive holes 111 arranged in 2 rows×2 columns defined by the intersection of any two adjacent rows and any two adjacent columns.

As described above, the core conductive hole 12 connected to the first conductive hole 111 is the first core conductive hole 121. A plurality of first conductive holes 111 are connected to the same first core conductive hole 121, and a plurality of first conductive holes 121 are arranged in an array. The core conductive hole 12 connected to the second conductive hole 12 is the second core conductive hole 122. A plurality of second conductive holes 112 are connected to the same second core conductive hole 122, and a plurality of second core conductive holes 122 are arranged in an array. In addition, a second core conductive hole 122 is arranged between the four first core conductive holes 121 defined by two adjacent rows and two adjacent columns.

All first core conductive holes 121 may be arranged in an array, and all second core conductive holes 122 may be arranged in an array. The array of the first core conductive holes 121 and the array of the second core conductive holes 122 may be staggered and nested. More specifically, for the array formed by the first core conductive holes 121, a second core conductive hole 122 may be correspondingly arranged in the middle area of the four first core conductive holes 121 arranged in 2 rows×2 columns defined by the intersection of any two adjacent rows and any two adjacent columns. As shown in FIG. 6, the first core conductive hole 121 and the second core conductive hole 122, which are closest to each other, are in different rows and columns.

In the packaging substrate provided by the embodiments of the present disclosure, in a direction perpendicular to the packaging substrate, a row of first conductive holes 111 and a row of second conductive holes 112 may be arranged between adjacent rows of first conductive holes 121 and rows of second conductive holes 122.

Refer to FIG. 4 and FIG. 6, since the array where the first conductive holes 111 are located is staggered with the array where the second conductive holes 112 are located, and there is a row of first conductive holes 111 and a row of second conductive holes 112 between adjacent rows of first core conductive holes 121 and rows of second core conductive holes 122, the first conductive holes 111 extending to the first core conductive layer and the second conductive holes 112 extending to the first core conductive layer are two adjacent conductive holes 111, thereby reducing the spacing between the first core conductive hole 121 and the second core conductive hole 122. In the embodiment shown in FIG. 1 to FIG. 3, there are two rows of first conductive holes 111 and two rows of second conductive holes 112 between an adjacent row of first core conductive holes 121 and a row of second core conductive holes 122, and the spacing between the first core conductive holes 121 and the second core conductive holes 122 is relatively large.

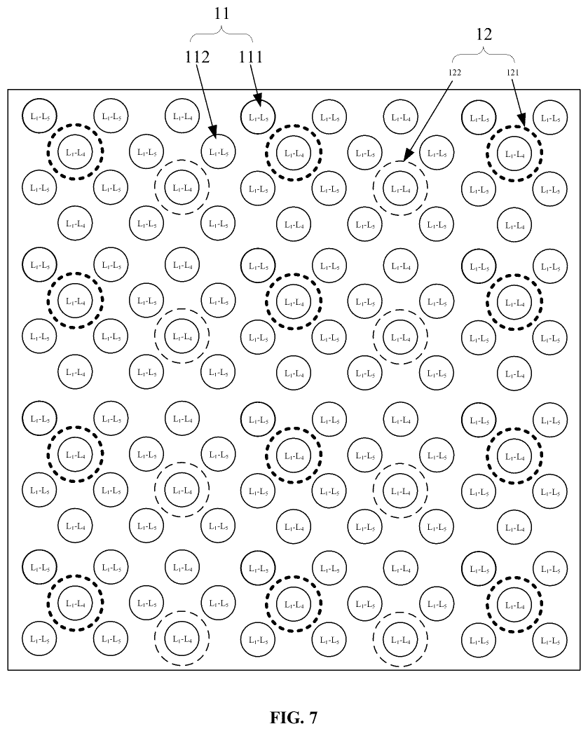

FIG. 7 is a schematic diagram of the number of extended layers of the conductive holes in the packaging substrate shown in FIG. 6. FIG. 7 illustrates the number of extended layers of each conductive hole 11 in FIG. 6. In the direction perpendicular to the packaging substrate, each core conductive hole 12 is surrounded by four conductive holes 11 arranged in 2 rows and 2 columns, and the four conductive holes 11 extend to the fifth conductive layer L₅ (the first core conductive hole layer). The first core conductive hole 121 has four first conductive holes 111 extending to the fifth conductive hole L₅, and the second conductive hole 122 has four second conductive holes 112 extending to the fifth conductive layer L₅.

The conductive hole layout shown in FIG. 7 is based on the topology obtained in the embodiment shown in FIG. 4. In the embodiment shown in FIG. 7, the first conductive holes 111 have 8 rows and 8 columns. For the array formed by the first conductive holes 111, the first conductive holes 111 in the first row, the second row, the fourth row, the fifth row, the seventh row, and the eighth row all extend from the first conductive hole L₁ to the fifth conductive layer L₅, as shown in L₁-L₅. The first conductive holes in the third and sixth rows extend from the first conductive layer L₁ to the fourth conductive layer L₄, as shown in L₁-L₄. The second conductive holes 112 have 7 rows and 7 columns. For the array formed by the second conductive holes 112, the second conductive holes 112 in the second row, the third row, the fifth row, and the sixth row all extend from the first conductive layer L₁ to the fifth conductive layer L₅, as shown in L₁-L₅. The second conductive holes 112 in the first row, the fourth row, and the seventh row all extend from the first conductive layer L₁ to the fourth conductive layer L₄, as shown in L₁-L₄.

As shown in FIG. 4-FIG. 7, in the direction perpendicular to the packaging substrate, the first core conductive hole 121 is disposed opposite to a second conductive hole 112, and the second conductive hole 112 extends from the first conductive layer L₁ to the a−1th conductive hole Lₐ₋₁. In the direction perpendicular to the packaging substrate, the second core conductive hole 122 is disposed opposite to a first conductive hole 111, and the first conductive hole 111 extends from the first conductive layer L₁ to the a−1th conductive hole Lₐ₋₁.

In the packaging substrate provided by the embodiments of the present disclosure, the spacing between two adjacent conductive holes 11 can be set to be no less than the process standard required for arranging the core conductive hole 12 in the core conductive layer such that the adjacent first conductive hole 111 and the second conductive hole 112 can both extend to the first core conductive layer, the first core conductive hole 121 can be arranged adjacent to the first conductive hole 111, and the second core conductive hole 122 can be arranged adjacent to the second conductive hole 112. In this way, the spacing between the first core conductive hole 121 and the second core conductive hole 122 can be reduced.

Next, an FC-BGA packaging substrate is taken as an example to compare the embodiment shown in FIG. 1 and the embodiment shown in FIG. 4.

In the FC-BGA packaging substrate, an aperture A of the conductive hole 11 may be 100 μm, and an aperture B of the core conductive hole 12 may be larger than the aperture A of the conductive hole 11. The embodiments shown in FIG. 1 and FIG. 4 have the same apertures A and B.

In the embodiment shown in FIG. 1, the spacing C1 between two adjacent conductive holes 11 is 30 μm, and the corresponding conductive bump center distance D1=A+C1=130 μm. Therefore, the center distance between two adjacent conductive holes 11 connected to the same potential is \sqrt{2}×D1=\sqrt{2}×130 μm, that is, the center distance between two adjacent first conductive holes 111 and two adjacent second conductive holes 112 is \sqrt{2}×130 μm.

In the embodiment shown in FIG. 4, since the spacing between two adjacent conductive holes 11 cannot be less than the process standard required for laying out the core conductive holes 12 in the core conductive layer, when compared with the embodiment shown in FIG. 1, the spacing between adjacent conductive holes 11 is increased, thereby increasing the center distance between two adjacent conductive holes 11. In the embodiment shown in FIG. 4, the spacing between two adjacent conductive holes 11 is C2, and the center distance between two adjacent conductive holes 11 is D2, then C2>C1, D2>D1. Therefore, compared with the embodiment shown in FIG. 1, the center distance between two adjacent conductive holes 11 connected to the same potential is increased by \sqrt{2}×D1−\sqrt{2}×D1=\sqrt{2}×(D2−130) in the embodiment shown in FIG. 4.

Assume that there are n rows and n columns of first conductive holes 111 connected to the power supply, as long as the condition of \sqrt{2}×(D2−130)×n≤\sqrt{2}×130 is met, the embodiment shown in FIG. 4 can increase the spacing between two adjacent conductive holes 11 while having the same number of first conductive holes 111 as the embodiment shown in FIG. 1. That is, the chip can have the same power conductive bumps. In some embodiments, n may be a positive integer greater than 1. Based on the principle, when the packaging substrate area is equal to E*E, the embodiment shown in FIG. 4 can have the same number of first conductive holes 111 as the embodiment shown in FIG. 1, and the chip connected to the two can have the same number of power conductive bumps. In some embodiments, E=\sqrt{2}×130 (n−1). At this time, while meeting the number requirements of power conductive bumps for the chip design, the requirements of the packaging substrate for packing and power integrity can also be met.

For the embodiment shown in FIG. 1, when the packaging substrate area is equal to E*E, as shown in FIG. 2 and FIG. 3, if the first conductive holes 111 are arranged in 8 rows and 8 columns, the second conductive holes 12 are correspondingly arranged in 8 rows and 8 columns. For the embodiment shown in FIG. 4, when the packaging substrate area is equal to E*E, as shown in FIG. 6 and FIG. 7, if the first conductive holes 111 are arranged in 8 rows and 8 columns, the second conductive holes 12 are correspondingly arranged in 7 rows and 7 columns.

Therefore, under the condition that the size of the packaging substrate remains unchanged, compared with the embodiment shown in FIG. 1 to FIG. 3, in the embodiment shown in FIG. 4 to FIG. 7, even though the number of second conductive holes 112 is reduced by one row and one column, the number of first conductive holes 111 remains unchanged, and the number of core conductive holes 12 in increased. In this way, the spacing between the core conductive holes 12 is reduced, the loop inductance is reduced, and the performance of the chip packaging structure is improved.

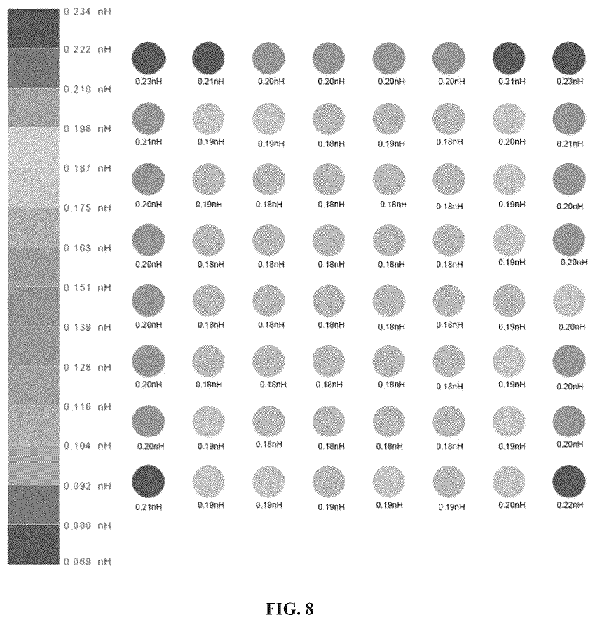

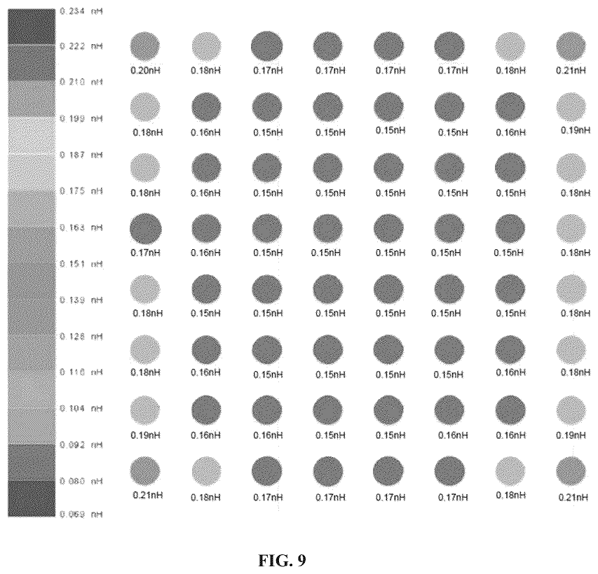

FIG. 8 is a simulation test diagram of a loop inductance of a power conductive bump in the packaging substate shown in FIG. 1, and FIG. 9 is a simulation test diagram of the loop inductance of the power conductive bump in the packaging substrate shown in FIG. 4. By comparing the loop inductance simulation data in FIG. 8 and FIG. 9, it can be seen that compared with the embodiment shown in FIG. 1, the packaging substrate prepared based on the embodiment shown in FIG. 4 can reduce the loop inductance and improve the performance of the chip packaging structure. In the simulation side views shown in FIG. 8 and FIG. 9, the color of the area corresponding to the conductive hole 11 represents the loop inductance. For example, for the conductive hole 11 in the upper left corner, the loop inductance of the embodiment shown in FIG. 8 is 0.23 nH, and the loop inductance of the method shown in FIG. 9 is 0.20 nH; for the conductive hole 11 in the upper right corner, the loop inductance of the embodiment shown in FIG. 8 is 0.23 nH, and the loop inductance of the method shown in FIG. 9 is 0.21 nH; for the conductive hole 11 in the lower left corner, the loop inductance of the embodiment shown in FIG. 8 is 0.21 nH, the loop inductance of the embodiment shown in FIG. 9 is 0.21 nH; for the conductive hole 11 in the lower right corner, the loop inductance of the embodiment shown in FIG. 8 is 0.22 nH, and the loop inductance of the method shown in FIG. 9 is 0.21 nH.

When the conductive holes 11 and the core conductive holes 12 are arranged in the manner shown in FIG. 4 to FIG. 7, the pattern structure of the conductive layer may also be as shown in FIG. 2 and FIG. 3. As described below, a plurality of conductive traces arranged in parallel may also be used.

When the conductive holes 11 and the core conductive holes 12 are arranged in the manner shown in FIG. 4 to FIG. 7, in other embodiments, a plurality of conductive traces arranged in parallel are arranged in the first conductive layer L₁ to the a−1^{th} conductive layer Lₐ₋₁. In the same conductive layer, an insulating gap may be arranged between two adjacent conductive traces, and the two adjacent conductive traces may be connected to different potentials. The difference from the embodiment shown in FIG. 2 and FIG. 3 is that in this embodiment, each conductive layer includes a plurality of parallel conductive traces in the first conductive layer L₁ to the a−1^{th} conductive layer Lₐ₋₁. In addition, in the same conductive layer, a gap is arranged between two adjacent conductive traces, and the two adjacent conductive traces are respectively used to connect conductive holes 11 with different potentials. In addition, as described above, the embodiments of the present disclosure can increase the spacing between two adjacent conductive holes 11. In this way, there is enough wiring space to layout multiple conductive traces such that two adjacent conductive traces are connected to different potentials respectively, thereby avoiding short circuit.

Compared with the embodiments shown in FIG. 2 and FIG. 3, two adjacent conductive traces may be respectively connected conductive holes 11 with different potentials without suing the entire conductive layer as the ground plane Lᵥₛₛ or the power plane L_{power}. In the first conductive layer L₁ to the a−1^{th} conductive layer Lₐ₋₁, each conductive layer may have a conductive trace for connecting to the power supply and a conductive trace for grounding, and these two conductive traces may be alternately arranged in the same plane to increase the current path of the power supply. In this way, the inductance of each conductive bump loop can be reduced without affecting the ground signal loop. Although the current path of the grounding conductive bump appears to be reduced, as shown in the simulation test results below, the loop inductance of the grounding conductive bump and the loop performance of the ground signal are not affected.

In the present disclosure, connecting to different potentials may indicate that one conductive trace is used to connect to the power supply and the other conductive trace is used to connect to the ground. As described above, the first conductive hole 111 and the second conductive hole 112 are connected to different potentials respectively. The first conductive hole 111 can be used to connect to the power conductive bump, and the second conductive hole 112 can be used to connect to the grounding conductive bump. At this time, in the same conductive layer, two adjacent conductive traces can be used to connect the first conductive hole 111 and the second conductive hole 112 respectively.

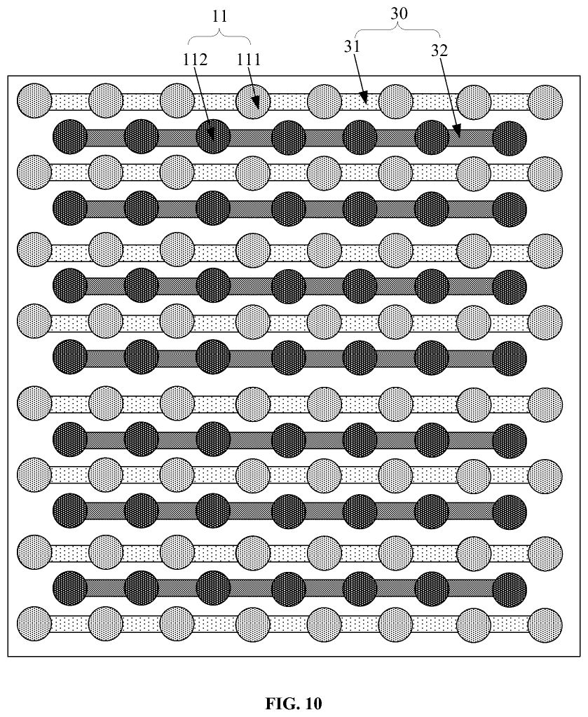

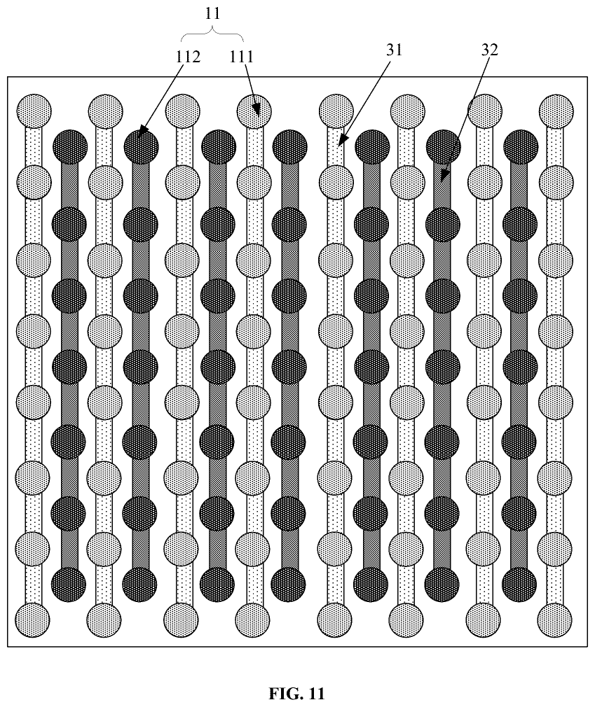

FIG. 10 is a graphic structure diagram of the conductive layer according to an embodiment of the present disclosure, and FIG. 11 is another graphic structure diagram of the conductive layer according to an embodiment of the present disclosure. FIG. 10 and FIG. 11 are diagrams illustrating the first conductive layer L₁ to the adjacent two conductive layers Lₐ₋₁. In the first conductive layer L₁ to the a−1^{th} conductive layer Lₐ₋₁ each include a plurality of conductive traces 30 arranged in parallel. In the same conductive layer, an insulating gap may be arranged between two adjacent conductive traces 30, and the two adjacent conductive traces may be used to connect the first conductive hole 111 and the second conductive hole 112, respectively.

Assume that the conductive trace 30 connected to the first conductive hole 111 is a first conductive trace 31, and the conductive trace 30 connected to the second conductive hole 112 is a second conductive trace 32. In the first conductive layer L₁ to the a−1^{th} conductive layer Lₐ₋₁, each conductive layer may include the first conductive traces 31 and the second conductive traces 32 alternately arranged in the same layer.

As shown in FIG. 10 and FIG. 11, for any two adjacent conductive layers from the first conductive layer L₁ to the a−1^{th} conductive layer Lₐ₋₁, the extension direction of the conductive trace 30 in one conductive layer is perpendicular to the extension direction of the conductive trace 30 in the other conductive layer. In this way, any two adjacent conductive layers can form a staggered fence-type conductive trace 30 layout structure, which can achieve a better effect of reducing the loop inductance of each conductive bump without affecting the return flow of the grounded conductive bump. When a=5, the conductive traces 30 in the first conductive layer L₁ and the third conductive layer L₃ can be arranged horizontally, and the conductive traces 30 in the second conductive layer L₂ and the fourth conductive layer Lₐ can be arranged vertically. Alternatively, the conductive traces 30 in the first conductive layer L₁ and the third conductive layer L₃ can be arranged vertically, and the conductive traces 30 in the second conductive layer L₂ and the fourth conductive layer L₄ can be arranged horizontally.

In the embodiments of the present disclosure, in the first conductive layer L₁ to the a−1^{th} conductive layer Lₐ₋₁, each conductive layer can include a plurality of conductive traces 30 arranged in parallel such that each conductive layer has a conductive trace 30 for connecting a row or a column of power conductive bumps in series. In this way, the series effect of the power supply conductive bumps is improved, the power supply has good planarity, the current path of the power supply conductive bumps is increase, the impedance is reduced, and the loop inductance of the power supply conductive bumps is reduced.

When each of the first conductive layer L₁ to the a−1^{th} conductive layer Lₐ₋₁ includes a plurality of conductive traces 30 arranged in parallel, the conductive traces 30 in each conductive layer may also be arranged in parallel. That is, each conductive layer can adopt the embodiment shown in FIG. 10, and the conductive traces 30 in each conductive layer can be arranged horizontally, or adopt the embodiment shown in FIG. 11, and the conductive traces 30 in each conductive layer can be arranged vertically.

In other embodiments, in the first conductive layer L₁ to the a−1^{th} conductive layer Lₐ₋₁, each conductive layer may include a concentric square conductive trace. In the same conductive layer, any two adjacent square-shaped conductive traces may be respectively used to access different potentials. That is, one conductive trace may be used to connect to the conductive hole 11, and the other conductive trace may be used to connect to the second conductive hole 112.

TABLE 1

| | | | FIG. 4 | |
|---|---|---|---|---|
| Loop conductance | FIG. 1 | FIG. 4 | with fence- | |
| of the power supply | Embodi- | Embodi- | type conductive | Improve- |
| conductive bump | ment | ment | traces | ment |
| Surrounding area | 230 pH | 200 pH | 170 pH | 26% |
| Middle area | 180 pH | 150 pH | 130 pH | 27% |

As shown in FIG. 1 above, the embodiment in FIG. 4 combined with the fence-type conductive trace can further reduce the loop inductance of the power conductive bump. Based on the embodiment of FIG. 4, the loop inductance of the power conductive bumps around the packaging substrate can be reduced from 200 pH to 170 pH, the loop inductance of the power conductive bump is optimized by 26%, the loop inductance of the power conductive bump in the middle of the packaging substrate is reduced from 150 pH to 130 pH, and the loop inductance of the power conductive bump is optimized by 27%.

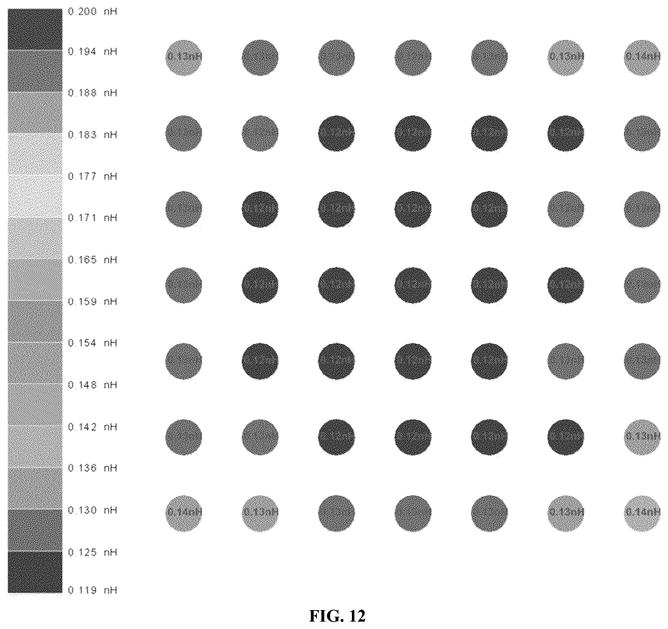

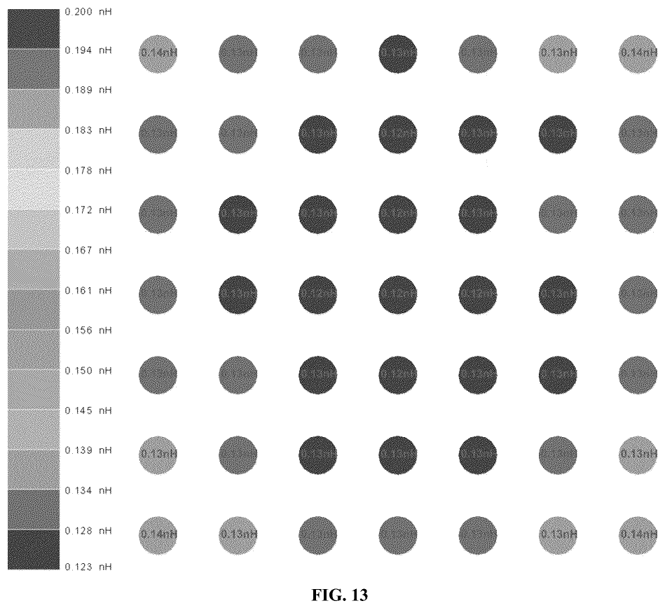

FIG. 12 is a simulation test diagram of the loop inductance of a grounded conductive bump in the packaging substate shown in FIG. 1, and FIG. 13 is simulation test diagram of the loop inductance of the grounded conductive bump in the packaging substate shown in FIG. 4 combined with fence-type conductive traces. By comparing the loop inductance simulation test results of the grounding conductive bumps shown in FIG. 12 and the FIG. 13, it can be seen that the technical solutions of the present disclosure can not only significantly reduce the loop inductance of the power conductive bump, but also has little effect on the loop inductance of the grounding conductive bump. In the simulation side views shown in FIG. 12 and FIG. 13, the chromaticity of the area corresponding to the conductive hole 11 represents the loop inductance. For example, for the conductive hole 11 in the upper left corner, the loop inductance of the embodiment shown in FIG. 12 is 0.13 nH, and the loop inductance of the embodiment shown in FIG. 13 is 0.14 nH; for the conductive hole 11 in the upper right corner, the loop inductance of the embodiment shown in FIG. 12 is 0.14 nH, and the loop inductance of the embodiment shown in FIG. 13 is 0.14 nH; for the conductive hole 11 in the lower left corner, the loop inductance of the embodiment shown in FIG. 12 is 0.14 nH, and the loop inductance of the embodiment shown in FIG. 13 is 0.14 nH.; for the conductive hole 11 in the lower right corner, the loop inductance of the embodiment shown in FIG. 12 is 0.14 nH, and the loop inductance of the embodiment shown in FIG. 13 is 0.14 nH.

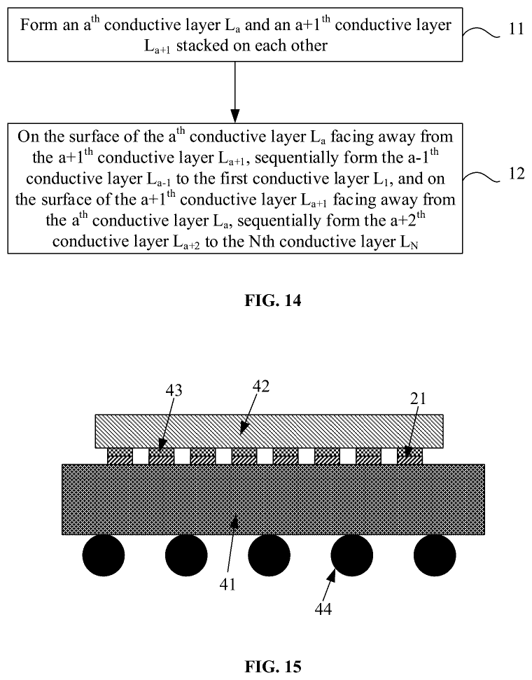

Based on the packaging substrate provided in the foregoing embodiments, an embodiment of the present disclosure also provides a method for manufacturing the above packaging substrate. FIG. 14 is a flowchart of a process for manufacturing a packaging substrate according to an embodiment of the present disclosure. As shown in FIG. 14 and the structural diagram of the packaging substrate provided in the foregoing embodiments, the packaging substrate has a first conductive layer L₁ to an N^{th} conductive layer LN stacked in sequence, and an insulating layer 13 is provided between two adjacent conductive layers. The method will be described in detail below.

11, forming an a^{th} conductive layer Lₐ and an a+1^{th} conductive layer Lₐ₊₁ stacked on each other.

In some embodiments, the a^{th} conductive layer Lₐ may be the first core conductive layer, the a+1^{th} conductive layer Lₐ₊₁ may be the second core conductive layer, a may be a positive integer, and 1<a<N−1. The first core conductive layer and the second core conductive layer may be connected via core conductive holes.

12, on the surface of the a^{th} conductive layer Lₐ facing away from the a+1^{th} conductive layer Lₐ₊₁, sequentially forming the a−1^{th} conductive layer Lₐ₋₁ to the first conductive layer L₁, and on the surface of the a+1^{th} conductive layer Lₐ₊₁ facing away from the a^{th} conductive layer Lₐ, sequentially forming the a+2^{th} conductive layer Lₐ+2 to the N^{th} conductive layer LN.

In some embodiments, the first conductive layer L₁ may include a plurality of pads 21, which can be used to connect the conductive bumps at the bottom of the chip. A plurality of conductive holes 11 corresponding to the pads 21 may be arranged between the first conductive layer L₁ and the a^{th} conductive layer Lₐ. One end of the conductive hole 11 may be connected to the corresponding pad 21, and the other end may extend to the a^{th} conductive layer Lₐ at most and may be electrically connected to the corresponding core conductive hole 12. The spacing between two adjacent conductive holes 11 may not be less than the process standard required for laying out the core conductive holes 12 in the core conductive layer.

In the embodiments of the present disclosure, each conductive hole 11 may be prepared layer by layer. For example, for the conductive hole 11 extending from the first conductive layer L₁ to the a^{th} conductive layer Lₐ, in the process of preparing the i^{th} conductive layer L₁, the conductive hole 11 extending from the i^{th} conductive layer L₁ to the i+1^{th} conductive layer L₁+1 can be prepared, i being a positive integer, and i<a.

Based on the packaging substrate provided in the foregoing embodiments, an embodiment of the present disclosure also provides a chip packaging structure. FIG. 15 is a schematic diagram of a chip packaging structure according to an embodiment of the present disclosure.

As shown in FIG. 15, the chip packaging structure includes a packaging substrate 41 described in any of the foregoing embodiments, and a chip 42. The bottom of the chip 42 has a plurality of conductive bumps 43 which are connected and fixed to the pads 21 in the substrate 41 in a one-to-one relationship. The conductive bumps 43 in the chip 42 may include power conductive bumps and grounding conductive bumps. The conductive bumps on the chip 42 may correspond to the conductive holes 11 on the surface of the packaging substrate 41. Compared with the conventional chip structure, the spacing between the conductive bumps needs to be set based on the spacing between adjacent conductive holes 11. When the chip size remains unchanged, the number of conductive bumps will not be reduced as described above, and the power performance will not be affected. Although the number of rows and columns of grounding conductive bumps is reduced, the loop inductance of the grounding conductive bumps will not be affected based on the technical solutions of the present disclosure. In addition, the above simulation test results also show that the technical solutions of the present disclosure will not affect the loop inductance of the grounding conductive bumps while improving the power supply performance. That is, the grounding performance will not be affected.

In some embodiments, the packaging substrate 41 may be disposed away from the chip 42 and may include solder balls 44 for connecting to external circuits.

In the chip packaging structure provided in the embodiments of the present disclosure, by adopting the packaging substrate 41 provided in the above embodiment, not only the loop inductance of the power conductive bumps can be reduced, the loop inductance of the grounding conductive bumps will not be affected, thereby improving the performance of the chip packaging structure.

Embodiments in this specification are described in a progressive manner, and each embodiment focuses on the difference from other embodiments. Same and similar parts of the embodiments may refer to each other. As for the device disclosed in the embodiments, since it corresponds to the method disclosed in the embodiments, the description is relatively simple, and for relevant details, the reference may be made to the description of the method embodiments.

Units and algorithm steps of the examples described in conjunction with the embodiments disclosed herein may be implemented by electronic hardware, computer software or a combination of the two. To clearly illustrate the possible interchangeability between the hardware and software, in the above description, the composition and steps of each example have been generally described according to their functions. Whether these functions are executed by hardware or software depends on the specific application and design constraints of the technical solution. Those skilled in the art may use different methods to implement the described functions for each specific application, but such implementation should not be regarded as exceeding the scope of the present disclosure.

In the present disclosure, the drawings and descriptions of the embodiments are illustrative and not restrictive. The same drawing reference numerals identify the same structures throughout the description of the embodiments. In addition, figures may exaggerate the thickness of some layers, films, panels, areas, etc., for purposes of understanding and ease of description. It will also be understood that when an element such as a layer, film, region or substrate is referred to as being “on” another element, it may be directly on another element or intervening elements may be present. In addition, “on” refers to positioning an element on or below another element, but does not essentially mean positioning on the upper side of another element according to the direction of gravity.

The orientation or positional relationship indicated by the terms “upper,” “lower,” “top,” “bottom,” “inner,” “outer,” etc. are based on the orientation or positional relationship shown in the drawings, and are only for the convenience of describing the present disclosure, rather than indicating or implying that the device or element referred to must have a specific orientation, be constructed and operated in a specific orientation, and therefore cannot be construed as a limitation of the present disclosure. When a component is said to be “connected” to another component, it may be directly connected to the other component or there may be an intermediate component present at the same time.

It should also be noted that in this article, relational terms such as “first” and “second” are only used to distinguish one entity or operation from another entity or operation, and do not necessarily require or imply that there is such actual relationship or sequence between these entities or operations them. Furthermore, the terms “comprises,” “includes,” or any other variation thereof are intended to cover a non-exclusive inclusion, such that an article or device including a list of elements includes not only those elements, but also other elements not expressly listed. Or it also includes elements inherent to the article or equipment. Without further limitation, an element defined by the statement “comprises a . . . ” does not exclude the presence of other identical elements in an article or device that includes the above-mentioned element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the present disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A packaging substrate for chip packaging comprising:
a first conductive layer to an N^{th} conductive layer stacked in sequence, N being a positive integer greater than 3;
an insulating layer arranged between two adjacent conductive layers;
a plurality of pads disposed on the first conductive layer, the plurality of pads being used to connect a plurality of conductive bumps at the bottom of a chip; and
a plurality of conductive holes arranged one-to-one corresponding to the plurality of pads between the first conductive layer and an a^{th} conductive layer, one end of the conductive hole is connected to the corresponding pad, and the other end extending to the a^{th} conductive layer at most and being electrically connected to a corresponding core conductive hole, wherein:
the a^{th} conductive layer is a first core conductive layer and an a+1^{th} is a second core conductive layer, a being a positive integer, 1<a<N−1, the first core conductive layer and the second core conductive layer being connected via the core conductive hole; and
spacing between two adjacent conductive layers is not less than a space required for arranging the core conductive hole in the core conductive layer.

2. The packaging substrate of claim 1, wherein:
the plurality of pads in the first conductive layer include:
a plurality of first parts arranged in an array, the conductive hole connected to the first pads being a first conductive hole;
a plurality of second pads arranged in an array, the conductive hole connected to the second pads being a second conductive hole; and
a second pad arranged between four first pads define by two adjacent rows and two adjacent columns, wherein:
the first conductive hole and the second conductive hole are used to access different potentials, and the spacing between the first conductive hole and the second conductive hole is not less than the process standard.

3. The packaging substrate of claim 2, wherein:
the core conductive hole connected to the first conductive hole is a first core conductive hole, a plurality of first conductive holes being connected to the same first core conductive hole, a plurality of first core conductive holes being arranged in an array;
the core conductive hole connected to the second conductive hole is a second core conductive hole, a plurality of second conductive holes being connected to the same second core conductive hole, a plurality of second core conductive holes being arranged in an array; and
one second core conductive hole is arranged between each of the four first core conductive holes defined by two adjacent rows and two adjacent columns.

4. The packaging substrate of claim 3, wherein:
in a direction perpendicular to the packaging substrate, a row of the first conductive holes and a row of the second conductive holes are arranged between adjacent rows of the first core conductive holes and rows of the second core conductive holes.

5. The packaging substrate of claim 3, wherein:
in a direction perpendicular to the packaging substrate, the first core conductive hole is arranged opposite to one second conductive hole, and the second conductive hole extends from the first conductive layer to an a−1^{th} conductive layer; and
in the direction perpendicular to the packaging substrate, the second core conductive hole is arranged opposite to one first conductive hole, and the first conductive hole extends from the first conductive layer to the a−1^{th} conductive layer.

6. The packaging substrate of claim 2, wherein:
the first conductive layer to the a−1^{th} conductive layer each include a plurality of conductive traces arranged in parallel; and
in the same conductive layer, an insulating gap is arranged between two adjacent conductive traces, the two adjacent conductive traces being used to connect the first conductive hole and the second conductive hole respectively.

7. The packaging substrate of claim 6, wherein:
for any two adjacent conductive layers from the first conductive layer to the a−1^{th} conductive layer, an extension direction of the conductive traces in one conductive layer is perpendicular to the extension direction of the conductive traces in the other conductive layer.

8. The packaging substrate of claim 1, wherein:
the number of conductive layers from the first conductive layer to the a^{th} conductive layer is the same as the number of conductive layers from the a+1^{th} conductive layer to the N^{th} conductive layer;
the a+1^{th} conductive layer to the N^{th} conductive layer and the first conductive layer to the a^{th} conductive layer have symmetrically arranged conductive holes; and
the conductive traces from the a+1^{th} conductive layer to the N^{th} conductive layer and from the first conductive layer to the a^{th} conductive layer are symmetrically arranged.

9. A manufacturing method for a packaging substrate, the packaging substrate including a first conductive layer to an N^{th} conductive layer stacked in sequence, an insulating layer arranged between two adjacent conductive layers, comprising:
forming an a^{th} conductive layer and an a+1^{th} conductive layer stacked on each other, the a^{th} conductive layer being a first core conductive layer, the a+1^{th} conductive layer being a second core conductive layer, a being a positive integer, 1<a<N−1, the first core conductive layer and the second core conductive layer being connected via a core conductive hole;
sequentially forming an a−1^{th} conductive layer to the first conductive layer on a surface of the a^{th} conductive layer facing away from the a+1^{th} conductive layer; and
sequentially forming an a+2^{th} conductive layer to the N^{th} conductive layer on a surface of the a+1^{th} conductive layer facing away from the a^{th} conductive layer, wherein:
the first conductive layer includes a plurality of pads, the plurality of pads being used to connect conductive bumps at the bottom of a chip;
a plurality of conductive holes are arranged one-to-one corresponding to the plurality of pads between the first conductive layer and an a^{th} conductive layer, one end of the conductive hole is connected to the corresponding pad, and the other end extending to the a^{th} conductive layer at most and being electrically connected to a corresponding core conductive hole; and
spacing between two adjacent conductive layers is not less than a space required for arranging the core conductive hole in the core conductive layer.

10. A chip packaging structure comprising:
a packaging substrate; the packaging substrate including a first conductive layer to an N^{th} conductive layer stacked in sequence, an insulating layer arranged between two adjacent conductive layers, and a plurality of pads disposed on the first conductive layer; and
a chip, the chip including a plurality of conductive bumps at the bottom of the chip, wherein:
the plurality of conductive bumps at the bottom of the chip are connected and fixed to the plurality of pads in the packaging substrate, and the packaging substrate comprising:
a first conductive layer to an N^{th} conductive layer stacked in sequence, N being a positive integer greater than 3; and
a plurality of conductive holes arranged one-to-one corresponding to the plurality of pads between the first conductive layer and an a^{th} conductive layer, one end of the conductive hole is connected to the corresponding pad, and the other end extending to the a^{th} conductive layer at most and being electrically connected to a corresponding core conductive hole wherein:
the a^{th} conductive layer is a first core conductive layer and an a+1^{th} is a second core conductive layer, a being a positive integer, 1<a<N−1, the first core conductive layer and the second core conductive layer being connected via the core conductive hole; and
spacing between two adjacent conductive layers is not less than a space required for arranging the core conductive hole in the core conductive layer.

11. The chip packaging structure of claim 10, wherein the plurality of pads in the first conductive layer of the packaging substrate include:
a plurality of first parts arranged in an array, the conductive hole connected to the first pads being a first conductive hole;
a plurality of second pads arranged in an array, the conductive hole connected to the second pads being a second conductive hole; and
a second pad arranged between four first pads define by two adjacent rows and two adjacent columns, wherein:
the first conductive hole and the second conductive hole are used to access different potentials, and the spacing between the first conductive hole and the second conductive hole is not less than the process standard.

12. The chip packaging structure of claim 11, wherein in the packaging substrate:
the core conductive hole connected to the first conductive hole is a first core conductive hole, a plurality of first conductive holes being connected to the same first core conductive hole, a plurality of first core conductive holes being arranged in an array;
the core conductive hole connected to the second conductive hole is a second core conductive hole, a plurality of second conductive holes being connected to the same second core conductive hole, a plurality of second core conductive holes being arranged in an array; and
one second core conductive hole is arranged between each of the four first core conductive holes defined by two adjacent rows and two adjacent columns.

13. The chip packaging structure of claim 12, wherein in the packaging substrate:
in a direction perpendicular to the packaging substrate, a row of the first conductive holes and a row of the second conductive holes are arranged between adjacent rows of the first core conductive holes and rows of the second core conductive holes in the packaging substrate.

14. The chip packaging structure of claim 12, wherein in the packaging substrate:
in a direction perpendicular to the packaging substrate, the first core conductive hole is arranged opposite to one second conductive hole, and the second conductive hole extends from the first conductive layer to an a−1^{th} conductive layer; and
in the direction perpendicular to the packaging substrate, the second core conductive hole is arranged opposite to one first conductive hole, and the first conductive hole extends from the first conductive layer to the a−1^{th} conductive layer.

15. The chip packaging structure of claim 11, wherein in the packaging substrate:
the first conductive layer to the a−1^{th} conductive layer each include a plurality of conductive traces arranged in parallel; and
in the same conductive layer, an insulating gap is arranged between two adjacent conductive traces, the two adjacent conductive traces being used to connect the first conductive hole and the second conductive hole respectively.

16. The chip packaging structure of claim 15, wherein in the packaging substrate:
for any two adjacent conductive layers from the first conductive layer to the a−1^{th} conductive layer, an extension direction of the conductive traces in one conductive layer is perpendicular to the extension direction of the conductive traces in the other conductive layer.

17. The packaging substrate of claim 10, wherein in the packaging substrate:
the number of conductive layers from the first conductive layer to the a^{th} conductive layer is the same as the number of conductive layers from the a+1^{th} conductive layer to the N^{th} conductive layer,
the a+1^{th} conductive layer to the N^{th} conductive layer and the first conductive layer to the at conductive layer have symmetrically arranged conductive holes; and
the conductive traces from the a+1^{th} conductive layer to the N^{th} conductive layer and from the first conductive layer to the at conductive layer are symmetrically arranged.
